(19) United States
(12) Patent Application Publication
(10) Pub. No.: US 2025/0393182 A1
(43) Pub. Date: Dec. 25, 2025

(54) PRINTED CIRCUIT BOARD HOLDER AND METHOD THEREOF

(71) Applicant: NANYA TECHNOLOGY CORPORATION, New Taipei City (TW)

(72) Inventors: Yi-Ju CHEN, New Taipei City (TW); Ching-Chung WANG, New Taipei City (TW)

(21) Appl. No.: 18/751,376

(22) Filed: Jun. 24, 2024

(51) Int. Cl. H05K 13/00

(52) U.S. Cl. CPC H05K 13/0015

(57) ABSTRACT

A printed circuit board holder includes a plate body and a plurality of limiting pieces. The plate body has a first surface, a second surface and a third surface. The third surface is connected between the first surface and the second surface. The first surface and the third surface together form a trench. The first surface and the second surface are of different levels. The third surface partially surrounds the trench. Two terminal edges of the third surface define a first opening therebetween. The limiting pieces are connected with the plate body and at least partially protrude from the third surface. Each of the limiting pieces and the first surface form a gap therebetween. The gaps are configured to accommodate a printed circuit board.

### BACKGROUND

### TECHNICAL FIELD

The present disclosure relates to printed circuit board holders and methods of holding a printed circuit board. More particularly, the present disclosure relates to holding a printed circuit board for testing by at least one probe.

### DESCRIPTION OF RELATED ART

As the demand for electronic devices has been increasing nowadays, the quality standard of various components of electronic devices becomes an important issue of the industry. Apart from improving the technology level of the components, the maintenance of high quality of the components during production is also an important issue.

For example, probe stations are in general used to test the electrical behavior of electronic components in the industry. Therefore, the measures to enhance the efficiency and accuracy of testing to the electronic components are undoubtedly an important issue on which the industry highly concerns.

### SUMMARY

A technical aspect of the present disclosure is to provide a printed circuit board holder, which can firmly hold a printed circuit board while maintaining the flatness of the printed circuit board, thus improving the efficiency and accuracy of the subsequent tests to be carried out on the printed circuit board.

According to an embodiment of the present disclosure, a printed circuit board holder includes a plate body and a plurality of limiting pieces. The plate body has a first surface, a second surface and a third surface. The third surface is connected between the first surface and the second surface. The first surface and the third surface together form a trench. The first surface and the second surface are of different levels. The third surface partially surrounds the trench. Two terminal edges of the third surface define a first opening therebetween. The limiting pieces are connected with the plate body and at least partially protrude from the third surface. Each of the limiting pieces and the first surface form a gap therebetween. The gaps are configured to accommodate a printed circuit board.

In one or more embodiments of the present disclosure, the limiting pieces are separated from each other.

In one or more embodiments of the present disclosure, the printed circuit board holder further includes a plurality of fasteners. Each of the fasteners is connected between a corresponding one of the limiting pieces and the plate body, such that a size of each of the gaps is adjustable.

In one or more embodiments of the present disclosure, the plate body has a plurality of fourth surfaces and a plurality of fifth surfaces. Each of the fourth surfaces is connected between the first surface and a corresponding one of the fifth surfaces. Each of the fourth surfaces and a corresponding one of the fifth surfaces together form a groove communicated with the trench. The first surface and the fifth surfaces are of different levels. Each of the fourth surfaces partially surrounds a corresponding one of the grooves. Two terminal edges of each of the fourth surfaces define a second opening therebetween. Each of the second openings is communicated with the first opening.

In one or more embodiments of the present disclosure, each of the grooves extends away from a corresponding one of the second openings, and the grooves are parallel with each other.

In one or more embodiments of the present disclosure, the grooves are spaced apart from the third surface.

In one or more embodiments of the present disclosure, the printed circuit board holder further includes a cover. The cover is configured to be mounted on the first surface and cover the said one of the grooves.

In one or more embodiments of the present disclosure, the printed circuit board holder further includes a pair of locking pieces. The locking pieces are opposite to each other. Each of the locking pieces is connected with the plate body and is at least partially extendable from the third surface.

In one or more embodiments of the present disclosure, each of the locking pieces includes a fixed portion and a moving portion. The fixed portion is connected with the plate body. The moving portion is connected with the fixed portion and is configured to elastically move relative to the fixed portion to protrude out of the third surface or to embed into the third surface.

In one or more embodiments of the present disclosure, each of the moving portions has an inclined surface facing to the first opening.

In one or more embodiments of the present disclosure, the locking pieces are located between the first opening and the limiting pieces.

In one or more embodiments of the present disclosure, the plate body has a circular shape.

In one or more embodiments of the present disclosure, the limiting pieces are symmetrically distributed around the trench.

A technical aspect of the present disclosure is to provide a method of holding a printed circuit board for testing, which can firmly hold a printed circuit board while maintaining the flatness of the printed circuit board, thus improving the efficiency and accuracy of the subsequent tests to be carried out on the printed circuit board.

According to an embodiment of the present disclosure, a method of holding a printed circuit board includes: sliding the printed circuit board into a trench of a plate body with a plurality of chips disposed on the printed circuit board respectively accommodated in one of a plurality of grooves of the plate body, the grooves being communicated with the trench; accommodating at least one cable of the printed circuit board in one of the grooves; abutting a first edge of the printed circuit board against an inner wall of the plate body; fastening a plurality of limiting pieces to the plate body such that the limiting pieces press the printed circuit board against the plate body; and mounting a cover on the plate body to cover the cable and abut against a second edge of the printed circuit board, the second edge being opposite to the first edge.

In one or more embodiments of the present disclosure, the method further includes: sliding the printed circuit board includes: pressing against a pair of locking pieces disposed on the plate body by the printed circuit board during sliding such that the locking pieces are elastically embedded into the plate body; and recovering the locking pieces after the first edge of the printed circuit board abutting against the inner wall of the plate body, such that the locking pieces at least partially protrude out of the plate body and abut against the second edge of the printed circuit board.

The above-mentioned embodiments of the present disclosure have at least the following advantages:

(1) Since a user can use the fasteners to press the limiting pieces against the first surface of the plate body, such that the printed circuit board can be tightly sandwiched and firmly secured between the limiting pieces and the plate body, the printed circuit board is prevented from loosening from the printed circuit board holder.

(2) Since the limiting pieces press on the regions of the printed circuit board near the edge, the printed circuit board is effectively prevented from bending and maintained to be flat, facilitating the subsequent tests to be carried out on the printed circuit board.

(3) Since the moving portion of each of the locking pieces at least partially abuts against the second edge of the printed circuit board after the printed circuit board is placed at the proper position on the printed circuit board holder, the printed circuit board is prevented from loosening from the printed circuit board holder.

### BRIEF DESCRIPTION OF THE DRAWINGS

The disclosure can be more fully understood by reading the following detailed description of the embodiments, with reference made to the accompanying drawings as follows:

FIG. 1 is a top view of a printed circuit board holder according to an embodiment of the present disclosure;

FIG. 2 is a front view of the printed circuit board holder of FIG. 1;

FIG. 3 is a top view of the printed circuit board holder of FIG. 1, in which a printed circuit board is being slid into the trench of the plate body;

FIG. 4 is an enlarged view of zone M of FIG. 3;

FIG. 5 is a top view of the printed circuit board holder of FIG. 3, in which a first edge of the printed circuit board abuts against the third surface of the plate body;

FIG. 6 is an enlarged view of zone N of FIG. 5;

FIG. 7 is a cross-sectional view along the section line A-A of FIG. 5; and

FIG. 8 is a flow chart of a method of holding a printed circuit board according to an embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

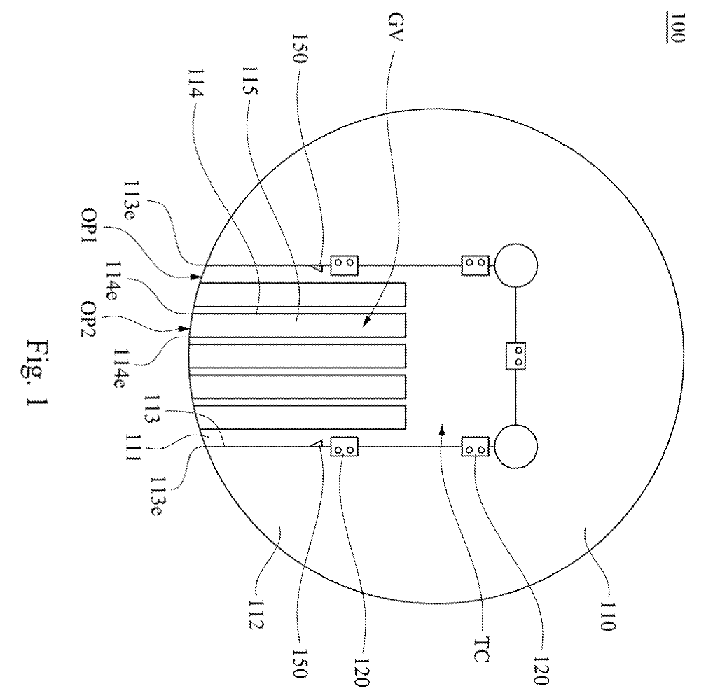

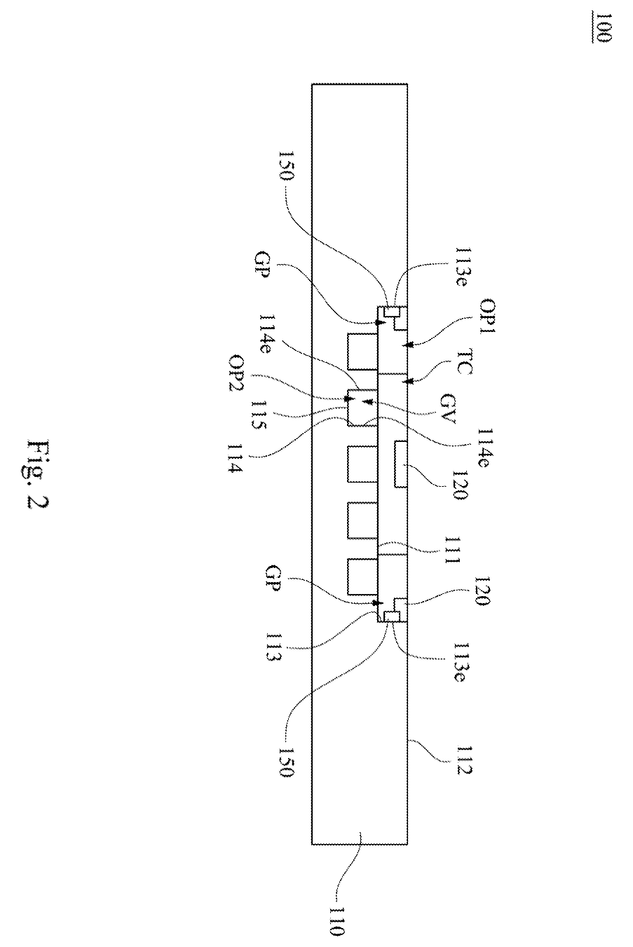

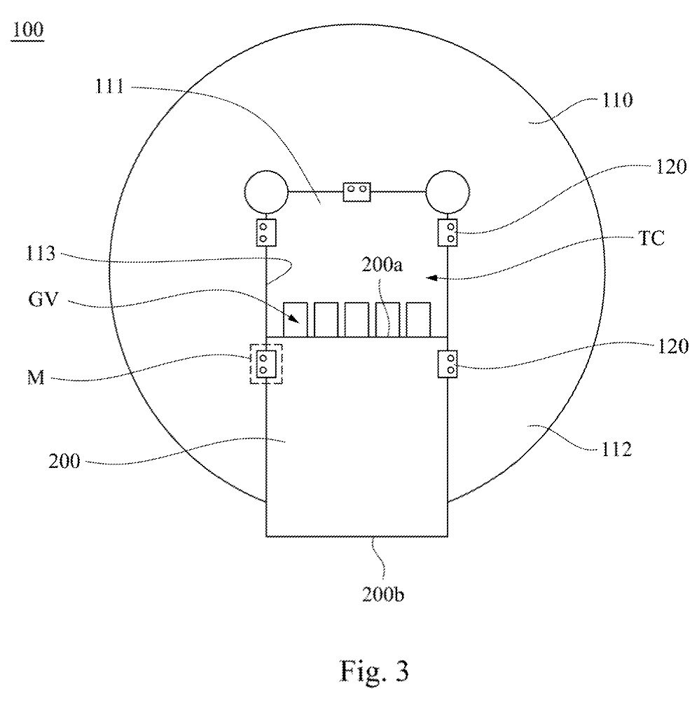

Reference is made to FIGS. 1-2. FIG. 1 is a top view of a printed circuit board holder 100 according to an embodiment of the present disclosure. FIG. 2 is a front view of the printed circuit board holder 100 of FIG. 1. In this embodiment, as shown in FIGS. 1-2, a printed circuit board holder 100 includes a plate body 110 and a plurality of limiting pieces 120. The plate body 110 has a first surface 111, a second surface 112 and a third surface 113. The third surface 113 is connected between the first surface 111 and the second surface 112. The first surface 111 and the third surface 113 together form a trench TC. The first surface 111 and the second surface 112 are of different levels. The third surface 113 partially surrounds the trench TC. Two terminal edges 113e of the third surface 113 define a first opening OP1 therebetween. The limiting pieces 120 are connected with the plate body 110 and at least partially protrude from the third surface 113 of the plate body 110. Each of the limiting pieces 120 and the first surface 111 of the plate body 110 form a gap GP therebetween. The gaps GP are configured to accommodate a printed circuit board 200 (please see FIG. 3 for the printed circuit board 200).

In practical applications, the plate body 110 has a circular shape, such that the printed circuit board holder 100 can be properly placed on a probe station (not shown) which is used to carry out various tests for wafers.

In addition, as shown in FIG. 1, the limiting pieces 120 are separated from each other. This means the limiting pieces 120 are spaced apart from each other. Moreover, as shown in FIG. 1, the limiting pieces 120 are symmetrically distributed around the trench TC.

Furthermore, as shown in FIGS. 1-2, the plate body 110 has a plurality of fourth surfaces 114 and a plurality of fifth surfaces 115. Each of the fourth surfaces 114 is connected between the first surface 111 and a corresponding one of the fifth surfaces 115. Each of the fourth surfaces 114 and a corresponding one of the fifth surfaces 115 together form a groove GV communicated with the trench TC. The first surface 111 and the fifth surfaces 115 are of different levels. Each of the fourth surfaces 114 partially surrounds a corresponding one of the grooves GV. Two terminal edges 114e of each of the fourth surfaces 114 define a second opening OP2 therebetween, and the second opening OP2 is communicated with a corresponding one of the grooves GV. Moreover, each of the second openings OP2 is communicated with the first opening OP1. In order words, the trench TC, the grooves GV, the first opening OP1 and the second openings OP2 are spatially communicated with each other.

To be specific, as shown in FIG. 1, each of the grooves GV extends away from a corresponding one of the second openings OP2, and the grooves GV are parallel with each other.

Furthermore, as shown in FIGS. 1-2, the grooves GV are spaced apart from the third surface 113. This means there exists at least a portion of the first surface 111 located between the outermost one of the grooves GV and the third surface 113 for providing support to the printed circuit board 200.

On the other hand, as shown in FIGS. 1-2, the printed circuit board holder 100 further includes a pair of locking pieces 150. The locking pieces 150 are opposite to each other. Each of the locking pieces 150 is connected with the plate body 110 and is at least partially extendable from the third surface 113 of the plate body 110.

Furthermore, in this embodiment, as shown in FIG. 1, the locking pieces 150 are located between the first opening OP1 and the limiting pieces 120. This means the locking pieces 150 are closer to the first opening OP1 than the limiting pieces 120 to the first opening OP1.

Reference is made to FIG. 3. FIG. 3 is a top view of the printed circuit board holder 100 of FIG. 1, in which a printed circuit board 200 is being slid into the trench TC of the plate body 110. In this embodiment, as shown in FIG. 3, a printed circuit board 200 is being slid into the trench TC of the plate body 110 and the printed circuit board 200 is pressing against the locking pieces 150, such that the locking pieces 150 are embedded into the third surface 113 of the plate body 110 (and the locking pieces 150 are not shown in FIG. 3, please refer to FIGS. 1-2 for the locking pieces 150). In this way, the printed circuit board 200 is able to slide along the trench TC while rubbing against the first surface 111 and the third surface 113 of the plate body 110.

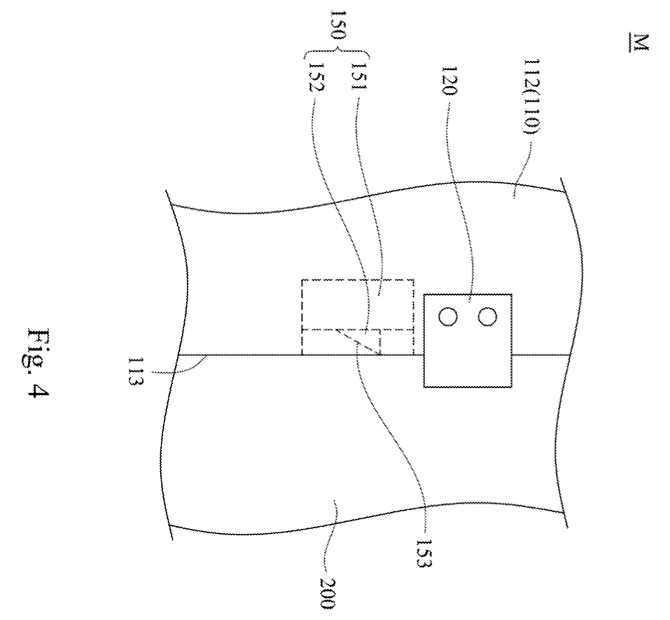

Reference is made to FIG. 4. FIG. 4 is an enlarged view of zone M of FIG. 3. In this embodiment, as shown in FIG. 4, the locking piece 150 includes a fixed portion 151 and a moving portion 152. The fixed portion 151 of the locking piece 150 is connected with the plate body 110. The moving portion 152 of the locking piece 150 is connected with the fixed portion 151 and is configured to elastically move relative to the fixed portion 151 to protrude out of the third surface 113 or to embed into the third surface 113 of the plate body 110. The fixed portion 151 and the moving portion 152 are shown by hidden lines in FIG. 4 since the locking piece 150 is entirely embedded into the plate body 110.

Furthermore, as shown in FIG. 4, each of the moving portions 152 has an inclined surface 153 facing to the first opening OP1 (please see FIGS. 1-3 for the first opening OP1). Therefore, when the printed circuit board 200 initially gets in contact with the moving portions 152 of the locking piece 150, the printed circuit board 200 firstly presses on the inclined surfaces 153 of the moving portions 152, which facilitates the moving portions 152 to elastically move relative to the fixed portions 151 to embed into the third surface 113 of the plate body 110.

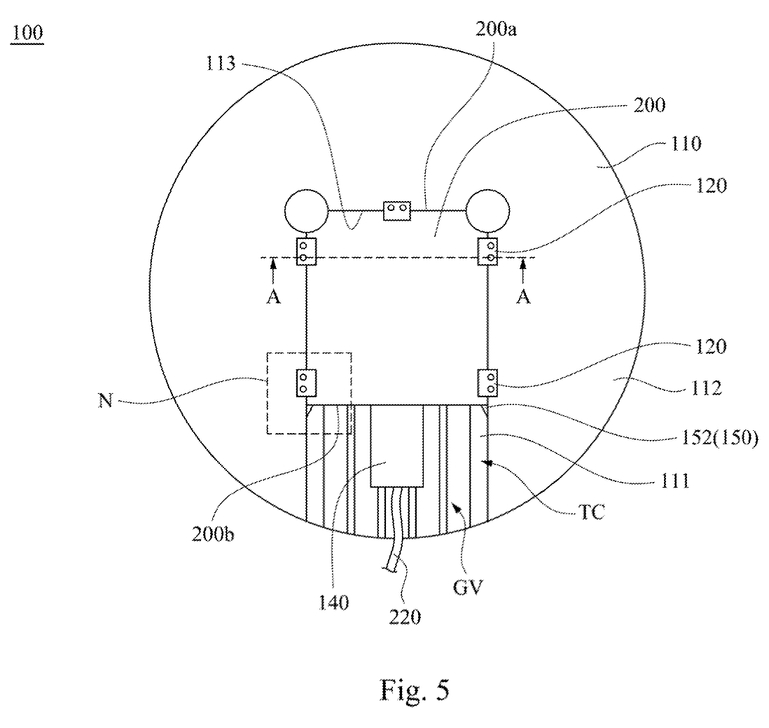

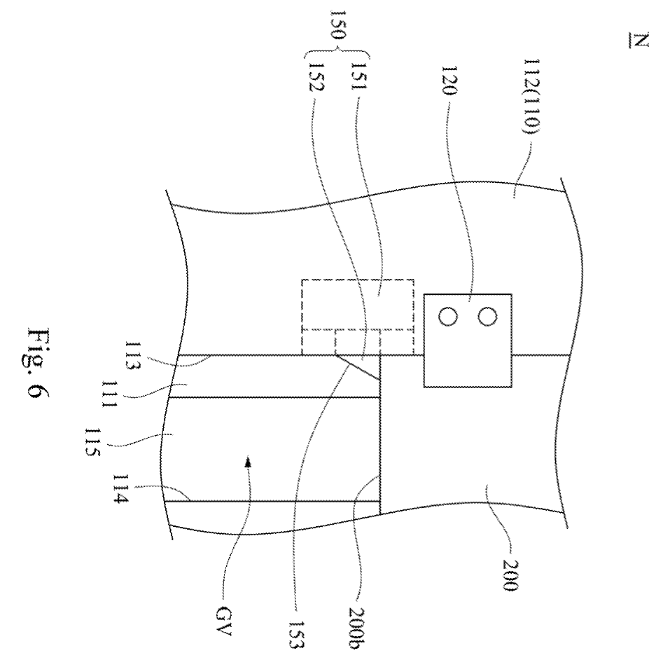

Reference is made to FIGS. 5-6. FIG. 5 is a top view of the printed circuit board holder 100 of FIG. 3, in which a first edge 200a of the printed circuit board 200 abuts against the third surface 113 of the plate body 110. FIG. 6 is an enlarged view of zone N of FIG. 5. As shown in FIG. 5, when a first edge 200a of the printed circuit board 200 abuts against the third surface 113 of the plate body 110, the printed circuit board 200 is placed at a proper position on the printed circuit board holder 100. At this point, as shown in FIG. 6, the moving portion 152 of the locking piece 150 is no longer pressed by the printed circuit board 200. Consequently, the moving portion 152 of the locking piece 150 then elastically protrudes out of the third surface 113 of the plate body 110 relative to the fixed portion 151, as shown in FIG. 6. Furthermore, as shown in FIG. 6, the moving portion 152 of the locking piece 150 at least partially abuts against a second edge 200b of the printed circuit board 200, in which the second edge 200b is opposite to the first edge 200a of the printed circuit board 200. In this way, the printed circuit board 200 is prevented from loosening from the printed circuit board holder 100.

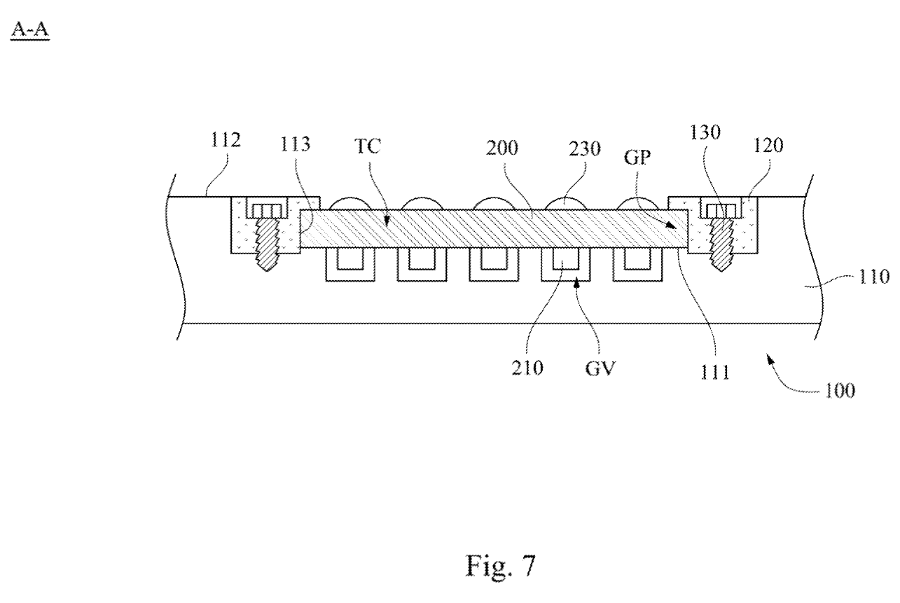

Reference is made to FIG. 7. FIG. 7 is a cross-sectional view along the section line A-A of FIG. 5. In this embodiment, as shown in FIG. 7, the printed circuit board holder 100 further includes a plurality of fasteners 130. Each of the fasteners 130 is connected between a corresponding one of the limiting pieces 120 and the plate body 110, such that a size of each of the gaps GP is adjustable. In other words, a user can use the fasteners 130 to press the limiting pieces 120 against the first surface 111 of the plate body 110 to reduce the vertical distance between each of the limiting pieces 120 and the first surface 111, such that the printed circuit board 200 can be tightly sandwiched and firmly secured between the limiting pieces 120 and the plate body 110. Thus, the printed circuit board 200 is prevented from loosening from the printed circuit board holder 100. Moreover, for example, each of the fasteners 130 is a screw. For the sake of drawing simplification, the fasteners 130 are not shown in other figures.

In addition, as shown in FIG. 7, since the limiting pieces 120 press on the regions of the printed circuit board 200 near the edge, the printed circuit board 200 is effectively prevented from bending and maintained to be flat, facilitating the subsequent tests to be carried out on the printed circuit board 200.

Moreover, as shown in FIG. 7, a plurality of chips 210 is disposed on the printed circuit board 200 and the chips 210 are respectively accommodated in the grooves GV of the plate body 110. It should be noted that, the presence of the grooves GV on the printed circuit board holder 100 allows the chips 210 to accommodate therein and move along such that the printed circuit board 200 can be slid into the trench TC on the first surface 111 of the plate body 110. When an electrical test is carried out to the printed circuit board 200, a probe (not shown) can be used to contact with the conductive pads 230 located on the side of the printed circuit board 200 opposite to the chips 210. For the sake of drawing simplification, the conductive pads 230 are not shown in other figures.

On the other hand, in this embodiment, as shown in FIG. 5, the printed circuit board holder 100 further includes a cover 140. The cover 140 is configured to be mounted on the first surface 111 of the plate body 110 and cover one of the grooves GV in which at least one cable 220 of the printed circuit board 200 is accommodated. As an additional security measure, the cover 140 further abuts against the second edge 200b of the printed circuit board 200, such that the printed circuit board 200 is further prevented from loosening from the printed circuit board holder 100. In practical applications, for example, the cover 140 is mounted on the first surface 111 of the plate body 110 by screwing or clamping. However, this does not intend to limit the present disclosure.

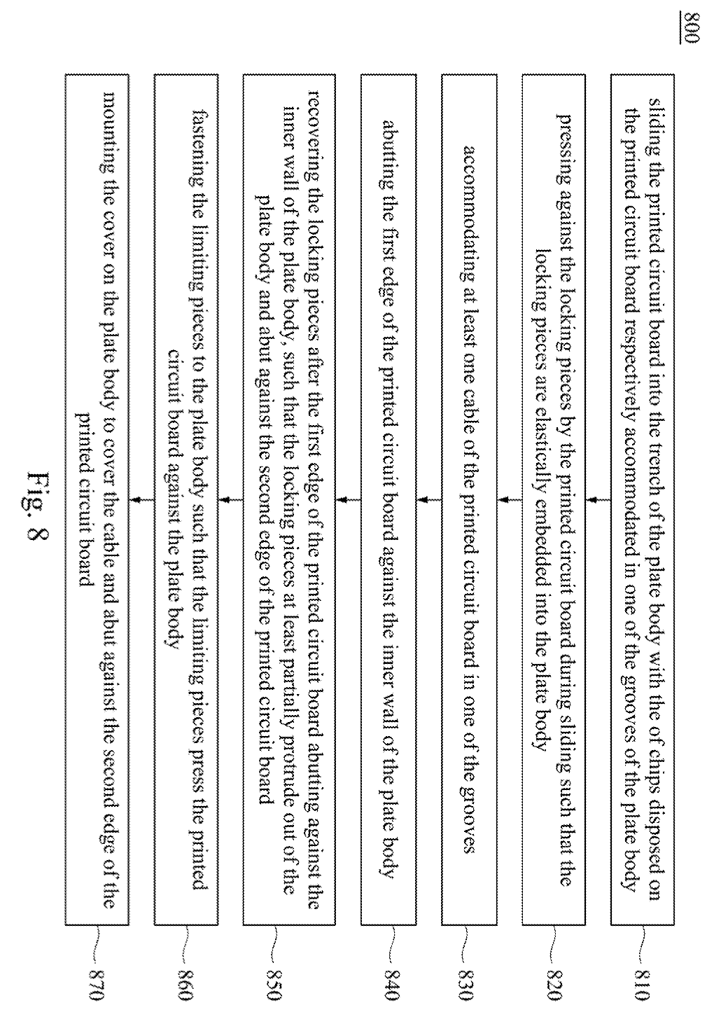

Reference is made to FIG. 8. FIG. 8 is a flow chart of a method 800 of holding a printed circuit board according to an embodiment of the present disclosure. Apart from the printed circuit board holder 100 as mentioned above, another aspect of the present disclosure provides a method 800 of holding a printed circuit board. As shown in FIG. 8, the method 800 of holding a printed circuit board includes the following procedures, which should be understood that the order of procedures mentioned below can be changed as per actual requirements, and some of the procedures may be executed simultaneously or partially simultaneously unless their sequence is explicitly stated:

Procedure 810: sliding the printed circuit board 200 into the trench TC of the plate body 110 with the of chips 210 disposed on the printed circuit board 200 respectively accommodated in one of the grooves GV of the plate body 110.

Procedure 820: pressing against the locking pieces 150 by the printed circuit board 200 during sliding such that the locking pieces 150 are elastically embedded into the plate body 110.

Procedure 830: accommodating at least one cable 220 of the printed circuit board 200 in one of the grooves GV.

Procedure 840: abutting the first edge 200a of the printed circuit board 200 against the inner wall (i.e., the third surface 113) of the plate body 110.

Procedure 850: recovering the locking pieces 150 after the first edge 200a of the printed circuit board 200 abutting against the inner wall of the plate body 110, such that the locking pieces 150 at least partially protrude out of the plate body 110 and abut against the second edge 200b of the printed circuit board 200.

Procedure 860: fastening the limiting pieces 120 to the plate body 110 such that the limiting pieces 120 press the printed circuit board 200 against the plate body 110.

Procedure 870: mounting the cover 140 on the plate body 110 to cover the cable 220 and abut against the second edge 200b of the printed circuit board 200.

In conclusion, the aforementioned embodiments of the present disclosure have at least the following advantages:

(1) Since a user can use the fasteners to press the limiting pieces against the first surface of the plate body, such that the printed circuit board can be tightly sandwiched and firmly secured between the limiting pieces and the plate body, the printed circuit board is prevented from loosening from the printed circuit board holder.

(2) Since the limiting pieces press on the regions of the printed circuit board near the edge, the printed circuit board is effectively prevented from bending and maintained to be flat, facilitating the subsequent tests to be carried out on the printed circuit board.

(3) Since the moving portion of each of the locking pieces at least partially abuts against the second edge of the printed circuit board after the printed circuit board is placed at the proper position on the printed circuit board holder, the printed circuit board is prevented from loosening from the printed circuit board holder.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A printed circuit board holder, comprising:
a plate body having a first surface, a second surface and a third surface, the third surface connecting between the first surface and the second surface, the first surface and the third surface together forming a trench, the first surface and the second surface being of different levels, the third surface partially surrounding the trench, two terminal edges of the third surface defining a first opening therebetween; and
a plurality of limiting pieces connected with the plate body and at least partially protruding from the third surface, each of the limiting pieces and the first surface forming a gap therebetween,
wherein the gaps are configured to accommodate a printed circuit board.

2. The printed circuit board holder of claim 1, wherein the limiting pieces are separated from each other.

3. The printed circuit board holder of claim 1, further comprising:
a plurality of fasteners, each of the fasteners being connected between a corresponding one of the limiting pieces and the plate body, such that a size of each of the gaps is adjustable.

4. The printed circuit board holder of claim 1, wherein the plate body has a plurality of fourth surfaces and a plurality of fifth surfaces, each of the fourth surfaces is connected between the first surface and a corresponding one of the fifth surfaces, each of the fourth surfaces and a corresponding one of the fifth surfaces together form a groove communicated with the trench, the first surface and the fifth surfaces are of different levels, each of the fourth surfaces partially surrounds a corresponding one of the grooves, two terminal edges of each of the fourth surfaces define a second opening therebetween, each of the second openings is communicated with the first opening.

5. The printed circuit board holder of claim 4, wherein each of the grooves extends away from a corresponding one of the second openings, and the grooves are parallel with each other.

6. The printed circuit board holder of claim 4, wherein the grooves are spaced apart from the third surface.

7. The printed circuit board holder of claim 4, further comprising:
a cover configured to be mounted on the first surface and cover the said one of the grooves.

8. The printed circuit board holder of claim 1, further comprising:
a pair of locking pieces opposite to each other, each of the locking pieces being connected with the plate body and at least partially extendable from the third surface.

9. The printed circuit board holder of claim 8, wherein each of the locking pieces comprises a fixed portion and a moving portion, the fixed portion is connected with the plate body, the moving portion is connected with the fixed portion and is configured to elastically move relative to the fixed portion to protrude out of the third surface or to embed into the third surface.

10. The printed circuit board holder of claim 9, wherein each of the moving portions has an inclined surface facing to the first opening.

11. The printed circuit board holder of claim 8, wherein the locking pieces are located between the first opening and the limiting pieces.

12. The printed circuit board holder of claim 1, wherein the plate body has a circular shape.

13. The printed circuit board holder of claim 1, wherein the limiting pieces are symmetrically distributed around the trench.

14. A method of holding a printed circuit board, comprising:
sliding the printed circuit board into a trench of a plate body with a plurality of chips disposed on the printed circuit board respectively accommodated in one of a plurality of grooves of the plate body, the grooves being communicated with the trench;
accommodating at least one cable of the printed circuit board in one of the grooves;
abutting a first edge of the printed circuit board against an inner wall of the plate body;
fastening a plurality of limiting pieces to the plate body such that the limiting pieces press the printed circuit board against the plate body; and
mounting a cover on the plate body to cover the cable and abut against a second edge of the printed circuit board, the second edge being opposite to the first edge.

15. The method of claim 14, further comprising:
pressing against a pair of locking pieces disposed on the plate body by the printed circuit board during sliding such that the locking pieces are elastically embedded into the plate body; and
recovering the locking pieces after the first edge of the printed circuit board abutting against the inner wall of the plate body, such that the locking pieces at least partially protrude out of the plate body and abut against the second edge of the printed circuit board.
